(19) United States
(12) Patent Application Publication
(10) Pub. No.: US 2024/0402414 A1
(43) Pub. Date: Dec. 5, 2024

(54) Packaging Member and Manufacturing Method therefor, Backlight Source Assembly, and Display Apparatus

(71) Applicants: Beijing BOE Display Technology Co., Ltd., Beijing (CN); BOE Technology Group Co., Ltd., Beijing (CN)

(72) Inventors: Boning WANG, Beijing (CN); Hao WU, Beijing (CN); Jian REN, Beijing (CN); Yangli ZHENG, Beijing (CN); Naiqi MEN, Beijing (CN); Xiaoping ZHANG, Beijing (CN)

(21) Appl. No.: 18/698,012

(22) PCT Filed: Apr. 27, 2023
(86) PCT No.: PCT/CN2023/091312

§ 371 Date: Apr. 2, 2024

(30) Foreign Application Priority Data
Apr. 28, 2022 (CN) 202210470685.0

(51) Int. Cl. F21V 8/00; G02F 1/13357

(52) U.S. Cl. CPC G02B 6/0065; G02B 6/0016; G02B 6/0073; G02F 1/133603; G02F 1/133606; G02F 1/133615

(57) ABSTRACT

A packaging member and a manufacturing method therefor, a backlight source assembly, and a display apparatus. The packaging member comprises a cup-shaped support (1), a light-emitting chip (2), and a packaging glue (3) mixed with a photoluminescent material (4); the light-emitting chip (2) is fixed at the bottom of the support (1) and emits light towards an opening of the support (1); the packaging glue (3) covers the light-emitting chip (2); and the packaging member comprises a light scattering structure, and the light scattering structure is configured to scatter light.

### CROSS-REFERENCE TO RELATED APPLICATION

The present application is a U.S. National Phase Entry of International Application No. PCT/CN2023/091312 having an international filing date of Apr. 27, 2023, which claims priority of Chinese patent application No. 202210470685.0, entitled “Packaging Member and Manufacturing Method therefor, Backlight Source Assembly, and Display Apparatus”, filed to the CNIPA on Apr. 28, 2022. Contents of the above-identified applications should be interpreted as being incorporated into the present application by reference.

### TECHNICAL FIELD

Embodiments of the present disclosure relate to, but are not limited to, the field of display technology, and particularly to a packaging member and a manufacturing method therefor, a backlight source assembly, and a display apparatus.

### BACKGROUND

This section is intended to provide background or context for the embodiments set forth in the claims. The description herein is not recognized as prior art because it is included in this section.

In a liquid crystal display apparatus with an edge-lit backlight source, the color of the light emitted from the liquid crystal display apparatus at a position close to a light bar of the backlight source is quite different from the color of the light emitted from the liquid crystal display apparatus at a position away from the light bar.

### SUMMARY

The following is a summary of subject matters described herein in detail. This summary is not intended to limit the protection scope of the claims.

Embodiments of the present disclosure provide a packaging member and a manufacturing method therefor, a backlight source assembly, and a display apparatus.

Embodiments of the present disclosure mainly provide following technical schemes.

In a first aspect, an embodiment of the present disclosure provides a packaging member, including a cup-shaped support, a light-emitting chip and a packaging glue mixed with a photoluminescent material. The light-emitting chip is fixed at a bottom of the support and emits light towards an opening of the support, the packaging glue covers the light-emitting chip, the packaging member includes a light scattering structure, and the light scattering structure is configured to scatter light.

In some embodiments, the light scattering structure includes a plurality of grooves provided on a surface of the packaging glue away from the light-emitting chip, the grooves being recessed toward a direction close to the light-emitting chip.

In some embodiments, an inner surface of at least one of the plurality of grooves is formed by rotating a curve about an axis by 360°.

In some embodiments, the inner surface of the at least one of the plurality of grooves is a portion of a spherical shape or a portion of an ellipsoidal shape.

In some embodiments, a plurality of sub-grooves are further provided on an inner surface of at least one of the plurality of grooves.

In some embodiments, an inner surface of at least one of the plurality of sub-grooves is formed by rotating a curve about an axis by 360°.

In some embodiments, the inner surface of the at least one of the plurality of sub-grooves is a portion of a ball shape.

In some embodiments, the inner surface of the at least one of the plurality of sub-grooves is spike-shaped.

In some embodiments, orthographic projections of the plurality of grooves on a plane where the support is located are distributed in an array; or among the orthographic projections of the plurality of grooves on the plane where the support is located, orthographic projections of four grooves closest to each other are connected into a diamond shape.

In some exemplary embodiments, the light-emitting chip is a Light Emitting Diode (LED) chip.

In some embodiments, an inner surface of the support includes a plurality of convex reflective surfaces, and the light scattering structure includes the plurality of convex reflective surfaces.

In some embodiments, at least one of the plurality of convex reflective surfaces is a portion of a spherical surface or a portion of a conical surface.

In a second aspect, an embodiment of the present disclosure provides a manufacturing method for a packaging member, the packaging member being the packaging member described in one or more of the above exemplary embodiments, the manufacturing method including:
filling a support fixed with a light-emitting chip with a packaging glue mixed with a photoluminescent material, wherein the support is cup-shaped, the light-emitting chip is fixed at a bottom of the support and emits light towards an opening of the support, and the packaging glue covers the light-emitting chip; and
curing the packaging glue to form a light scattering structure for scattering light in the packaging member.

In some embodiments, the step of curing the packaging glue includes:
pressing a surface of the packaging glue away from the light-emitting chip by a mold, wherein a surface of the mold has a plurality of protrusions to form a plurality of grooves on the surface of the packaging glue away from the light-emitting chip, the grooves are recessed toward a direction close to the light-emitting chip, the plurality of grooves are configured to scatter light, and the light scattering structure includes the plurality of grooves; curing the packaging glue; and removing the mold.

In some embodiments, a surface of at least one of the plurality of protrusions is formed by rotating a curve about an axis by 360°.

In some embodiments, the surface of the at least one of the plurality of protrusions is a portion of a spherical shape or a portion of an ellipsoidal shape.

In some embodiments, a plurality of sub-protrusions are further provided on a surface of at least one of the plurality of protrusions.

In some embodiments, a surface of at least one of the plurality of sub-protrusions is formed by rotating a curve about an axis by 360°.

In some embodiments, the surface of the at least one of the plurality of sub-protrusions is a portion of a ball shape.

In some embodiments, the surface of the at least one of the plurality of sub-protrusions is spike-shaped.

In some embodiments, orthographic projections of the plurality of protrusions on a plane where the support is located are distributed in an array; or among the orthographic projections of the plurality of protrusions on the plane where the support is located, orthographic projections of four protrusions closest to each other are connected into a diamond shape.

In some embodiments, the light-emitting chip is an LED chip.

In some embodiments, an inner surface of the support includes a plurality of convex reflective surfaces, and the light scattering structure includes the plurality of convex reflective surfaces.

In some embodiments, at least one of the plurality of convex reflective surfaces is a portion of a spherical surface or a portion of a conical surface.

In a third aspect, an embodiment of the present disclosure provides a backlight source assembly, including the packaging member described in one or more of the above exemplary embodiments.

In a fourth aspect, an embodiment of the present disclosure provides a display apparatus, including the backlight source assembly described in one or more of the above exemplary embodiments.

Other features and advantages of the present disclosure will be set forth in the following specification, and moreover, partially become apparent from the specification, or are understood by implementing the present disclosure. Other advantages of the present disclosure may be achieved and obtained through solutions described in the specification and drawings.

Other aspects of the present disclosure may be comprehended after the drawings and the detailed descriptions are read and understood.

### BRIEF DESCRIPTION OF DRAWINGS

The accompanying drawings are intended to provide an understanding of technical schemes of the present application and form a part of the specification, and are used to explain the technical schemes of the present disclosure together with embodiments of the present disclosure, and not intended to form limitations to the technical schemes of the present disclosure. Shapes and sizes of components in the drawings do not reflect actual scales, and are only intended to schematically illustrate contents of the present disclosure.

FIG. 1 is a schematic structural diagram of an LED packaging member in some techniques;

FIG. 2 is a schematic structural diagram of a packaging member according to an exemplary embodiment of the present disclosure;

FIG. 3 is a front view of a packaging glue in a packaging member according to an exemplary embodiment of the present disclosure;

FIG. 4A is a first cross-sectional view of a light scattering structure on a packaging glue in a packaging member according to an exemplary embodiment of the present disclosure;

FIG. 4B is a second cross-sectional view of a light scattering structure on a packaging glue in a packaging member according to an exemplary embodiment of the present disclosure;

FIG. 4C is a third cross-sectional view of a light scattering structure on a packaging glue in a packaging member according to an exemplary embodiment of the present disclosure;

FIG. 4D is a fourth cross-sectional view of a light scattering structure on a packaging glue in a packaging member according to an exemplary embodiment of the present disclosure;

FIG. 5 is a schematic diagram of a light scattering principle of a light scattering structure in a packaging member according to an exemplary embodiment of the present disclosure;

FIG. 6 is a schematic diagram of an arrangement of light scattering structures in a packaging member according to an exemplary embodiment of the present disclosure;

FIG. 7 is a diagram of performance simulation comparison between a backlight source assembly including a packaging member according to some techniques and a backlight source assembly including a packaging member according to an exemplary embodiment of the present disclosure;

FIG. 8A is a top view of a support in a packaging member according to an exemplary embodiment of the present disclosure;

FIG. 8B is a cross-sectional view of the support shown in FIG. 8A;

FIG. 9 is a flow diagram of a manufacturing method for a packaging member according to an exemplary embodiment of the present disclosure;

FIG. 10 is a schematic diagram of an intermediate state of a packaging member during a manufacturing process according to an exemplary embodiment of the present disclosure; and

FIG. 11 is a cross-sectional view of a template according to an exemplary embodiment of the present disclosure.

### DETAILED DESCRIPTION

Multiple embodiments are described herein, but the description is exemplary rather than restrictive, and there may be more embodiments and implementation solutions within a scope contained in the embodiments described herein. Although many possible feature combinations are shown in the drawings and discussed in exemplary implementations, many other combinations of the disclosed features are possible. Unless expressly limited, any feature or element of any embodiment may be used in combination with, or may replace, any other feature or element in any other embodiment.

When a representative embodiment is described, a method or process may already be presented in a specific order of acts in the specification. However, to an extent that the method or the process does not depend on the specific order of the acts described herein, the method or the process should not be limited to the acts with the specific order. As will be understood by those of ordinary skill in the art, other act orders are possible. Therefore, the specific sequence of the acts illustrated in the specification should not be interpreted as a limitation on claims. Moreover, claims directed to the method and/or process should not be limited to performing their acts in a described order, and those skilled in the art may readily understand that these orders may be varied and still remain within the spirit and scope of the embodiments of the present disclosure.

Unless otherwise defined, technical terms or scientific terms used in the embodiments of the present disclosure shall have common meanings understood by people with ordinary skills in the field to which the present disclosure pertains. “First”, “second”, and similar terms used in the embodiments of the present disclosure do not represent any order, quantity, or importance, but are only used for distinguishing different components. “Include”, “contain”, or a similar term means that an element or object appearing before the term covers an element or object and equivalent thereof listed after the term and does not exclude other elements or objects. “Connect”, “couple”, or similar words are not limited to a physical or mechanical connection, but may include an electrical connection, whether direct or indirect.

The present disclosure will be further described below with reference to the embodiments shown in the drawings.

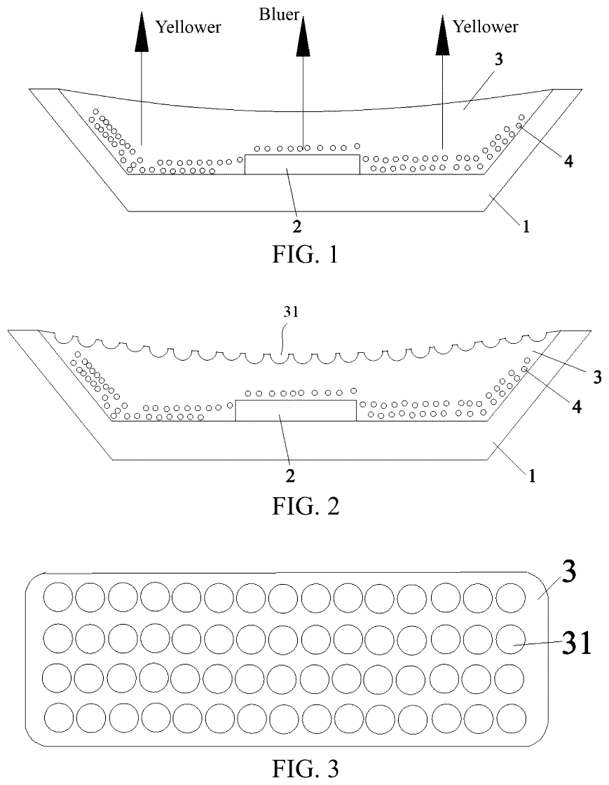

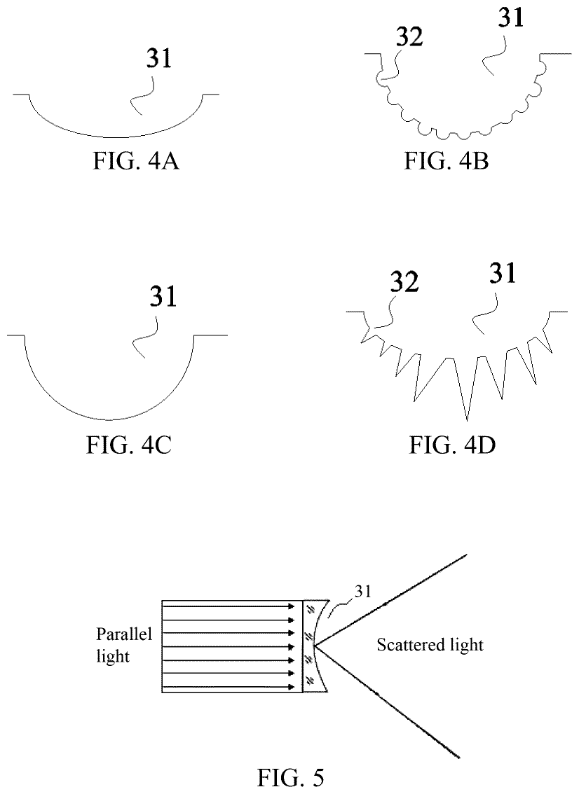

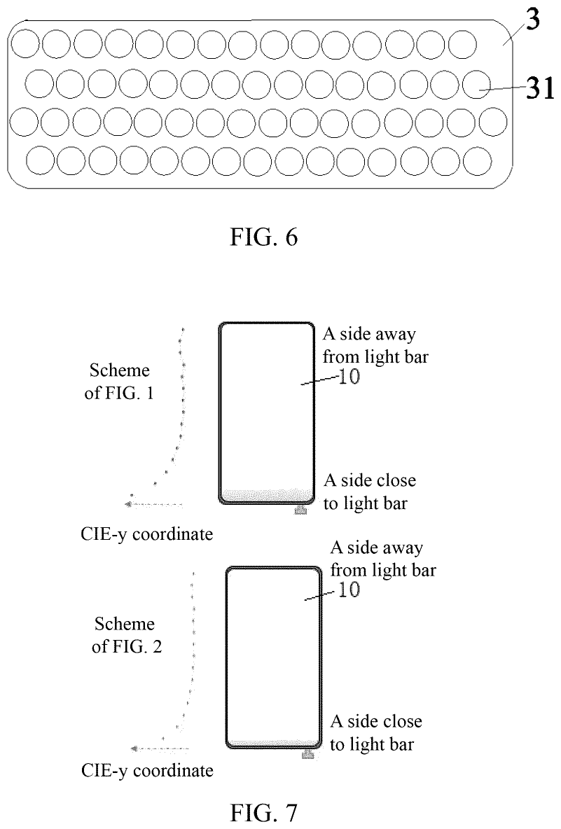

FIG. 1 is a schematic structural diagram of an LED packaging member in some techniques. As shown in FIG. 1, the LED packaging member in some techniques may include: a support 1, a light-emitting chip 2 and a packaging glue 3. The light-emitting chip 2 is fixed in a central region at a bottom of the support 1. The light-emitting chip 2 may emit blue light. The support 1 has an electrode structure (not shown) electrically connected to an electrode of the light-emitting chip 2. An inner surface of the support 1 may be a reflective surface. In order to stabilize the performance of packaging members manufactured in different batches, phosphor may be scattered on an upper surface of the light-emitting chip 2 and the inner surface of the support 1 by a centrifugal process. Thus, in the packaging member of some techniques, the blue light emitted by the light-emitting chip 2 will excite the phosphor to emit yellow light after passing through the phosphor in the packaging glue 3. Here, the inner surface of the support 1 may refer to a surface of the support 1 close to the light-emitting chip 2, and the upper surface of the light-emitting chip 2 may refer to a surface of the light-emitting chip 2 away from the support 1.

As shown in FIG. 1, yellow light may be obtained after the blue light emitted upward from a central region of the light-emitting chip 2 is excited by the phosphor in a central region of the packaging glue 3. The blue light emitted obliquely from the light-emitting chip 2 may excite the phosphor above the light-emitting chip 2 to emit yellow light, and may be emitted to an edge region of the support 1 to excite the phosphor in the edge region of the packaging glue 3 to emit yellow light again, so that the light emitted from the edge region of the packaging glue 3 is yellower than the light emitted from the central region of the packaging glue 3. In addition, the centrifugal process also causes the phosphor above the light-emitting chip 2 to be relatively sparse compared to the phosphor above the edge region at the bottom of the support 1, which causes the light emitted from the edge region of the packaging glue 3 to be yellower than the light emitted from the central region of the packaging glue 3. As can be seen, the color of the surface light field of the light-emitting chip 2 in the LED packaging member of some techniques is uneven.

FIG. 7 is a diagram of performance simulation comparison between a backlight source assembly including a packaging member according to some techniques and a backlight source assembly including a packaging member according to an exemplary embodiment of the present disclosure. A corresponding portion of the scheme of FIG. 1 in FIG. 7 schematically illustrates a simulation diagram of a backlight source assembly including a packaging member of some techniques. As shown in the corresponding portion of the scheme of FIG. 1 in FIG. 7, when the packaging member of some techniques is applied to manufacture an edge-lit backlight source assembly 10 or a direct-lit backlight source assembly 10, since the color of the surface light field of the light-emitting chip 2 in the LED packaging member of some techniques is uneven, the color in the region of the edge-lit backlight source assembly close to the light bar is greatly different from the color in the region of the edge-lit backlight source assembly away from the light bar.

As shown in FIG. 7, in the edge-lit backlight source assembly 10, the packaging member including the light-emitting chip 2 are usually arranged in a row near a short side of the backlight source assembly 10 so that the light bars formed may approximately constitute a line light source. The light-emitting chip 2 emits light toward the other short side of the backlight source assembly 10, and the line light source is converted into a uniform surface light source through an optical diaphragm such as a reflective sheet, a light guide plate, a prism sheet (none of which is shown in the figure).

As shown in FIG. 1, there is more blue light in a central region of a light emitting surface of the light-emitting chip 2, so that more blue light passes through a light guide plate to a region away from the light bar. In addition, there is more yellow light in an edge region of the light emitting surface of the light-emitting chip 2, so that the divergent yellow light is more likely to be emitted out of the backlight source assembly 10 from a vicinity of the region close to the light bar. Therefore, the unevenness of the color in the surface light field of the light-emitting chip 2 is a direct cause of the great difference in color between the region of the edge-lit backlight source assembly 10 close to the light bar and the region of the edge-lit backlight source assembly 10 away from the light bar. As can be seen, how to improve the color uniformity of the surface light field of the light-emitting chip 2 is very important for improving the color uniformity of the light emitted from the direct-lit backlight source assembly 10.

Based on the above analysis, an embodiment of the present disclosure provides a packaging member, which may improve the color uniformity of the surface light field of the light-emitting chip by providing a light scattering structure to scatter the light.

FIG. 2 is a schematic structural diagram of a packaging member according to an exemplary embodiment of the present disclosure. As shown in FIG. 2, the packaging member may include a cup-shaped support 1, a light-emitting chip 2, and a packaging glue 3 mixed with a photoluminescent material 4. The light-emitting chip 2 is fixed at a bottom of the support 1 and emits light towards an opening of the support 1, and the packaging glue 3 covers the light-emitting chip 2. The packaging member may further include a light scattering structure configured to scatter light.

In some embodiments, the packaging glue 3 is generally made of a polymer material which may be cured by light irradiation or heating. For example, a material of the packaging glue 3 may be silicone resin.

In some embodiments, the photoluminescent material 4 may be a phosphor which may emit light of another color under excitation of light emitted by the light-emitting chip 2. For example, the photoluminescent material 4 may be a fluoride phosphor, a silicate phosphor, a nitride phosphor, or the like. The exemplary embodiments of the present disclosure are not limited thereto.

In some embodiments, the light scattering structure may include a plurality of nanoparticles which may be doped within the packaging glue 3, thereby enabling the scattering of light.

In some embodiments, the light scattering structure 31 is provided on a side of the packaging glue 3 away from the light-emitting chip 2. As shown in FIG. 2, the light scattering structure may include a plurality of grooves 31 which may be provided on an upper surface of the packaging glue 3, thereby enabling the scattering of light. Here, the upper surface of the packaging glue 3 may refer to a surface of the packaging glue 3 away from the light-emitting chip 2. For example, as shown in FIG. 2, the grooves 31 may be recessed in a direction close to the light-emitting chip 2, that is, in a direction away from a light emitting side of the packaging member.

In some embodiments, as shown in FIG. 2, the grooves 31 on the surface of the packaging glue 3 are equivalent to concave lenses so that directions of light emitted from the packaging glue 3 are more dispersed.

In some embodiments, an inner surface of at least one of the plurality of grooves 31 may be formed by rotating a curve about an axis by 360°, which helps to improve the uniformity of light emitted from the groove 31 in a circumferential direction surrounding an opening of the groove 31.

In some embodiments, as shown in FIG. 4C, the inner surface of at least one of the plurality of grooves 31 is spherical.

In other embodiments, as shown in FIG. 4A, the inner surface of at least one of the plurality of grooves 31 is ellipsoidal.

In other embodiments, as shown in FIGS. 4B and 4D, a plurality of sub-grooves 32 may further be provided on the inner surface of at least one of the plurality of grooves 31.

A sub-groove 32 is smaller in size than a groove 31 in which the sub-groove 32 is located. The sub-grooves 32 allow a greater degree of light divergence, which is more conducive to improving color consistency between different regions of the backlight source assembly 10.

In some embodiments, as shown in FIG. 4B, an inner surface of at least one of the plurality of sub-grooves 32 is formed by rotating a curve about an axis by 360°. The light emitted from the groove 31 is relatively uniform in the circumferential direction surrounding the opening of the groove 31.

In some embodiments, as shown in FIG. 4B, the inner surface of the at least one of the plurality of sub-grooves 32 may be a portion of a ball shape. For example, the inner surface of the sub-groove 32 may be a portion of a spherical shape or a portion of an ellipsoidal shape. For example, the inner surface of the sub-groove 32 may be semi-spherical or semi-ellipsoidal.

In other embodiments, as shown in FIG. 4D, the inner surface of at least one of the plurality of sub-grooves 32 may be spike-shaped.

In some embodiments, in order to obtain a better light scattering effect, a spacing between adjacent grooves 31 may be provided as small as possible, while avoiding structural interference between the adjacent grooves 31.

In one or more of the above exemplary embodiments, dimensions and shapes of the plurality of grooves 31 may be the same or may be different. Dimensions and shapes of the plurality of sub-grooves 32 may be the same or may be different. In this way, a greater degree of freedom may be provided for the design of the packaging member.

FIG. 5 is a schematic diagram of a light scattering principle of a light scattering structure in a packaging member according to an exemplary embodiment of the present disclosure. As shown in FIG. 5, a light scattering structure implemented using a groove 31 is taken as an example. After light is scattered by the light scattering structure (i.e., the groove 31), the distribution of light of each color in multiple directions is more even, which may make the light field of the packaging member more uniform. Thus, in the backlight source assembly 10 including the packaging member, it is possible to reduce the color difference between the region close to the light bar and the region away from the light bar, so that the colors of the light emitted from the backlight source assembly 10 composed of the packaging member are closer in the region close to the light bar and the region away from the light bar.

In some embodiments of the present disclosure, as shown in FIG. 3, in a plane parallel to the packaging member, an orthographic projection of an upper surface of the packaging glue 3 on a plane where the support 1 is located may be rectangular (e.g., the four corners of the rectangle may be rounded or not chamfered). For example, a set of opposite sides of the rectangle may be in a range of 1 mm to 5 mm in length, and another set of opposite sides of the rectangle may be in a range of 0.1 mm to 1 mm in length.

In some embodiments, in a plane parallel to the packaging member, a distance between orthographic projections of the grooves 31 on the plane where the support 1 is located and an orthographic projection of an upper surface boundary of the packaging glue 3 on the plane where the support 1 is located is greater than 0.01 mm, so as to ensure the uniformity of light efficiency in an edge region of the cup opening.

In some embodiments, the groove 31 may be a spherical groove with a radius ranging from 0.001 mm to 0.025 mm. In this way, it may be ensured that the size limit of the conventional process will not be exceeded, and a good enough light scattering effect can be obtained.

In some embodiments, as shown in FIG. 3, orthographic projections of the plurality of grooves 31 on the plane where the support 1 is located are distributed in an array.

In some other embodiments, as shown in FIG. 6, orthographic projections of four grooves 31 closest to each other on the plane where the support 1 is located are connected to form a diamond shape.

In some embodiments, the light-emitting chip 2 may be an LED chip.

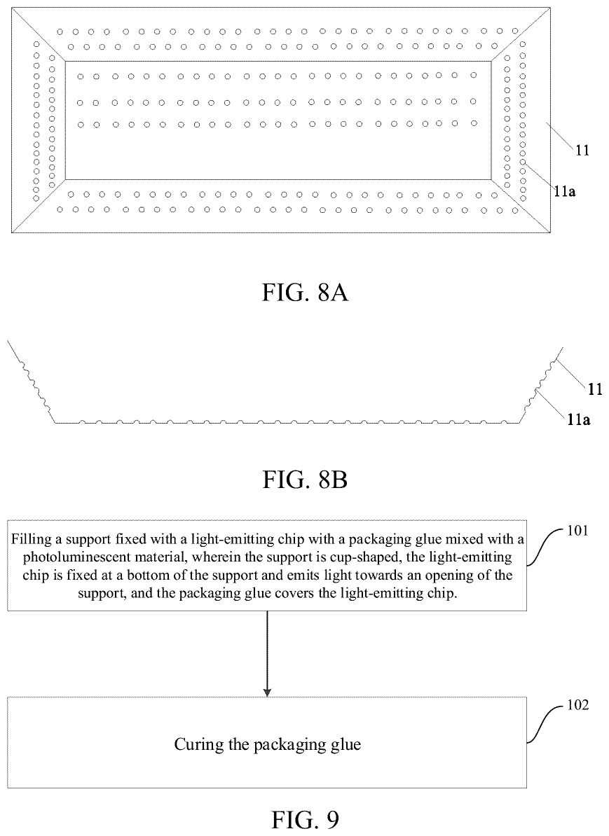

In some embodiments, as shown in FIGS. 8A and 8B, an inner surface 11 of the support 1 may include a plurality of convex reflective surfaces 11a, and the light scattering structure may include the plurality of convex reflective surfaces 11a. When the convex reflective surfaces 11a reflect part of the light emitted by the light-emitting chip 2 and part of the light excited by the photoluminescent material 4, emitting angles of the light are enlarged, so that the light emitted by the light-emitting chip 2 and the light excited by the photoluminescent material 4 are mixed more uniformly.

In some embodiments, as shown in FIG. 8A, at least one of the plurality of convex reflective surfaces 11a may be a portion of a spherical surface.

In some other embodiments, at least one of the plurality of convex reflective surfaces 11a may be a conical surface.

FIG. 7 is a diagram of performance simulation comparison between a backlight source assembly including a packaging member according to some techniques and a backlight source assembly including a packaging member according to an exemplary embodiment of the present disclosure. A corresponding portion of the scheme of FIG. 1 in FIG. 7 schematically illustrates a simulation diagram of a backlight source assembly including a packaging member of some techniques. A corresponding portion of the scheme of FIG. 2 in FIG. 7 schematically illustrates a simulation diagram of a backlight source assembly including a packaging member according to an exemplary embodiment of the present disclosure. As shown in FIG. 7, compared to the application of the packaging member according to some techniques to the manufacturing of an edge-lit backlight source assembly 10, the application of the backlight source assembly including the packaging member according to an embodiment of the present disclosure to the manufacturing of an edge-lit backlight source assembly 10 makes the color difference between the region of the edge-lit backlight source assembly close to the light bar and the region of the edge-lit backlight source assembly away from the light bar smaller.

Based on the same inventive concept, an embodiment of the present disclosure further provides a manufacturing method for a packaging member. FIG. 9 is a flow diagram of a manufacturing method for a packaging member according to an exemplary embodiment of the present disclosure. As shown in FIG. 9, the method may include the following steps.

Step 101: filling a support 1 fixed with a light-emitting chip 2 with a packaging glue 3 mixed with a photoluminescent material 4. The support 1 is cup-shaped, the light-emitting chip 2 is fixed at a bottom of the support 1 and emits light towards an opening of the support 1, and the packaging glue 3 covers the light-emitting chip 2.

In some embodiments, the light-emitting chip 2 may be fixed within the support 1 using a crystal-fixing process, and electrodes of the light-emitting chip 2 may then be electrically connected to electrodes on the support 1 via a welding wire process.

In some embodiments, the photoluminescent material 4 such as a phosphor may be mixed into the packaging glue 3, and then the packaging glue 3 is dropped into the support 1. In this way, the phosphor is concentrated at the bottom of the support 1 through a centrifugal process, thereby ensuring stable and consistent performance of products in different batches.

Step 102: curing the packaging glue. A light scattering structure for scattering light is formed in the packaging member.

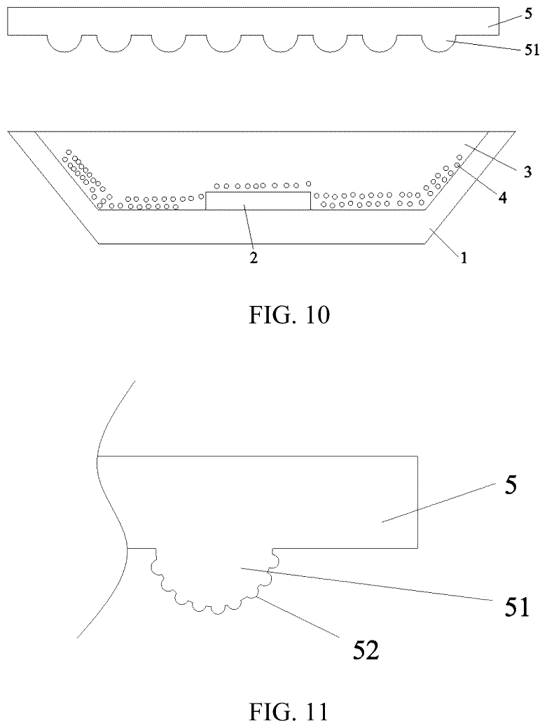

In some embodiments, as shown in FIG. 10, Step 102 may include pressing an upper surface of the packaging glue 3 with a mold 5 and curing the packaging glue 3, followed by removing the mold 5. Since a surface of the mold 5 has a plurality of protrusions 51, a plurality of grooves 31 may be formed on the upper surface of the packaging glue 3. The plurality of grooves 31 are configured to scatter light, and the light scattering structure includes the plurality of grooves 31.

In some embodiments, as shown in FIG. 10, Step 102 may include pressing a mold 5 toward the packaging glue 3 to form a plurality of grooves 31 on an upper surface of the packaging glue 3. Shapes of protrusions 51 are complementary to shapes of the grooves 31. The pressing of the mold 5 to the packaging glue 3 is maintained, and then baking is performed to cure the packaging glue 3.

In some embodiments, a surface of at least one of the plurality of protrusions 51 may be formed by rotating a curve about an axis by 360°.

In some embodiments, the surface of at least one of the plurality of protrusions 51 is a portion of a spherical shape or a portion of an ellipsoidal shape. For example, the surface of at least one of the plurality of protrusions 51 may be semi-spherical or semi-ellipsoidal.

In some embodiments, as shown in FIG. 11, a plurality of sub-protrusions 52 may further be provided on a surface of at least one of the plurality of protrusions 51.

In some embodiments, a surface of at least one of the plurality of sub-protrusions 52 may be formed by rotating a curve about an axis by 360°.

In some embodiments, the surface of at least one of the plurality of sub-protrusions 52 may be a portion of a ball shape (spherical, ellipsoidal, or the like) or may be spike-shaped. For example, the surface of at least one of the plurality of sub-protrusions 52 may have a semi-spherical shape, a semi-ellipsoidal shape, a tapered shape, or the like. The embodiments of the present disclosure are not limited thereto.

In some embodiments, orthographic projections of the plurality of protrusions 51 on a plane where the support 1 is located are distributed in an array; or, among the orthographic projections of the plurality of protrusions 51 on the plane where the support 1 is located, orthographic projections of four protrusions 51 closest to each other are connected into a diamond shape.

In some embodiments, the light-emitting chip 2 may be an LED chip.

In some embodiments, as shown in FIGS. 8A and 8B, an inner surface 11 of the support 1 includes a plurality of convex reflective surfaces 11a, and the light scattering structure includes the plurality of convex reflective surfaces 11a. The convex reflective surfaces 11a may protrude toward a light emitting side of the packaging member. When the convex reflective surfaces 11a reflect part of the light emitted by the light-emitting chip 2 and part of the light excited by the photoluminescent material 4, emitting angles of the light are enlarged, so that the light emitted by the light-emitting chip 2 and the light excited by the photoluminescent material 4 are mixed more uniformly.

In some embodiments, the support 1 may be formed by injection molding, and by designing a mold for injection molding, a plurality of convex structures are formed on the inner surface of the support 1. A layer of reflective material (e.g., electroplating or depositing a layer of silver) is then formed on the inner surface of the support 1. The reflective material covered on the convex structures form the convex reflective surfaces 11a.

In some embodiments, as shown in FIG. 8A, at least one of the plurality of convex reflective surfaces 11a may be a portion of a spherical surface. For example, at least one of the plurality of convex reflective surfaces 11a may be a semi-spherical surface, or a semi-ellipsoidal surface, or the like.

In some other embodiments, at least one of the plurality of convex reflective surfaces 11a may be a conical surface.

An embodiment of the present disclosure further provides a backlight source assembly 10, including the packaging member in one or more of the above exemplary embodiments. Thus, the light field uniformity of the light-emitting chip 2 may be improved by providing a light scattering structure in the packaging member to scatter light, thereby improving the color uniformity of the light emitted from the packaging member, and further improving the color uniformity of the light emitted from the backlight source assembly 10.

In some embodiments, the backlight source assembly 10 may be an edge-lit backlight source assembly 10 or a direct-lit backlight source assembly 10. For example, multiple layers of optical diaphragms (e.g., diffusion sheets, atomization sheets, prism sheets, and the like) may further be provided in the backlight source assembly 10.

The structure of the backlight source assembly 10 is not limited in embodiments of the present disclosure, and may be designed with reference to some techniques.

Based on the same inventive concept, an embodiment of the present disclosure further provides a display apparatus, which may include the backlight source assembly 10 in one or more of the above exemplary embodiments.

In some embodiments, the display apparatus may be any device or product with display function, such as a liquid crystal display module, a mobile phone, a display, a tablet computer, an electronic billboard, etc.

Embodiments of the present disclosure are described in a progressive manner, the same and similar parts among multiple embodiments can be referred to each other, and each embodiment focuses on its differences from other embodiments.

The protection scope of the present disclosure is not limited to the above-described embodiments, and it is apparent that modifications and variations of the present disclosure may be made by those skilled in the art without departing from the scope and spirit of the present disclosure. If these modifications and variations fall within the scope of the claims of the present disclosure and their equivalent techniques, the present disclosure is also intended to include these modifications and variations.

1. A packaging member, comprising a cup-shaped support, a light-emitting chip and a packaging glue mixed with a photoluminescent material, wherein the light-emitting chip is fixed at a bottom of the support and emits light towards an opening of the support, the packaging glue covers the light-emitting chip, the packaging member comprises a light scattering structure, and the light scattering structure is configured to scatter light.

2. The packaging member according to claim 1, wherein the light scattering structure comprises a plurality of grooves provided on a surface of the packaging glue away from the light-emitting chip, the grooves being recessed toward a direction close to the light-emitting chip.

3. The packaging member according to claim 2, wherein an inner surface of at least one of the plurality of grooves is formed by rotating a curve about an axis by 360°.

4. The packaging member according to claim 3, wherein the inner surface of the at least one of the plurality of grooves is a portion of a spherical shape or a portion of an ellipsoidal shape.

5. The packaging member according to claim 2, wherein a plurality of sub-grooves are further provided on an inner surface of at least one of the plurality of grooves; and
wherein an inner surface of at least one of the plurality of sub-grooves is formed by rotating a curve about an axis by 360°.

6. (canceled)

7. The packaging member according to claim 5, wherein the inner surface of the at least one of the plurality of sub-grooves is a portion of a ball shape.

8. The packaging member according to claim 5, wherein an inner surface of at least one of the plurality of sub-grooves is spike-shaped.

9. The packaging member according to claim 2, wherein orthographic projections of the plurality of grooves on a plane where the support is located are distributed in an array; or among the orthographic projections of the plurality of grooves on the plane where the support is located, orthographic projections of four grooves closest to each other are connected into a diamond shape.

10. The packaging member according to claim 1, wherein the light-emitting chip is an LED chip; or
wherein an inner surface of the support comprises a plurality of convex reflective surfaces, and the light scattering structure comprises the plurality of convex reflective surfaces.

11. (canceled)

12. The packaging member according to claim 4410, wherein at least one of the plurality of convex reflective surfaces is a portion of a spherical surface or a portion of a conical surface.

13. A manufacturing method for a packaging member, the packaging member being the packaging member according to claim 1, the manufacturing method comprising:
filling a support fixed with a light-emitting chip with a packaging glue mixed with a photoluminescent material, wherein the support is cup-shaped, the light-emitting chip is fixed at a bottom of the support and emits light towards an opening of the support, and the packaging glue covers the light-emitting chip; and
curing the packaging glue to form a light scattering structure for scattering light in the packaging member.

14. The method according to claim 13, wherein the step of curing the packaging glue comprises:
pressing a surface of the packaging glue away from the light-emitting chip by a mold, wherein a surface of the mold has a plurality of protrusions to form a plurality of grooves on the surface of the packaging glue away from the light-emitting chip, the grooves are recessed toward a direction close to the light-emitting chip, the plurality of grooves are configured to scatter light, and the light scattering structure comprises the plurality of grooves;
curing the packaging glue; and
removing the mold.

15. The method according to claim 14, wherein a surface of at least one of the plurality of protrusions is formed by rotating a curve about an axis by 360°; and
wherein the surface of the at least one of the plurality of protrusions is a portion of a spherical shape or a portion of an ellipsoidal shape.

16. (canceled)

17. The method according to claim 14, wherein a plurality of sub-protrusions are further provided on a surface of at least one of the plurality of protrusions; and
wherein a surface of at least one of the plurality of sub-protrusions is formed by rotating a curve about an axis by 360°.

18. (canceled)

19. The method according to claim 17, wherein the surface of the at least one of the plurality of sub-protrusions is a portion of a ball shape.

20. The method according to claim 17, wherein the surface of the at least one of the plurality of sub-protrusions is spike-shaped.

21. The method according to claim 14, wherein orthographic projections of the plurality of protrusions on a plane where the support is located are distributed in an array; or among the orthographic projections of the plurality of protrusions on the plane where the support is located, orthographic projections of four protrusions closest to each other are connected into a diamond shape; or
wherein the light-emitting chip is an LED chip.

22. (canceled)

23. The method according to claim 13, wherein an inner surface of the support comprises a plurality of convex reflective surfaces, and the light scattering structure comprises the plurality of convex reflective surfaces; and
wherein at least one of the plurality of convex reflective surfaces is a portion of a spherical surface or a portion of a conical surface.

24. (canceled)

25. A backlight source assembly, comprising the packaging member according to claim 1.

26. A display apparatus, comprising the backlight source assembly according to claim 25.
